(19) United States
(12) Patent Application Publication
(10) Pub. No.: US 2026/0031123 A1
(43) Pub. Date: Jan. 29, 2026

(54) MEMORY DEVICE WITH DIGIT LINE SLEW RATE CONTROL

(71) Applicant: Micron Technology, Inc., Boise, ID (US)

(72) Inventor: Makoto Kitagawa, Folsom, CA (US)

(21) Appl. No.: 19/265,452

(22) Filed: Jul. 10, 2025

Related U.S. Application Data
(60) Provisional application No. 63/676,534, filed on Jul. 29, 2024.

(51) Int. Cl. G11C 11/22

(52) U.S. Cl. CPC G11C 11/2273; G11C 11/221; G11C 11/2259

(57) ABSTRACT

An electronic device may include multiple memory cells, multiple digit lines, and multiple sense amplifiers each coupled to a memory cell through a target digit line and including an output stage. The output stage may be configured to produce an output signal driving the target digit line. The target digit line may be directly adjacent to one or more adjacent digit lines. The output stage may be configured to receive one or more switching signals each indicative of a logic state of an adjacent digit line and to control a slew rate of the output signal in the target digit line using the received one or more switching signals.

### PRIORITY APPLICATION

This application claims the benefit of priority to U.S. Provisional Application Ser. No. 63/676,534, filed Jul. 29, 2024, which is incorporated herein by reference in its entirety.

### BACKGROUND

Memory devices are widely used to store information in various electronic devices such as computers, wireless communication devices, cameras, digital displays, and the like. Information is stored by programming different states of a memory device. For example, binary devices most often store one of two states, often denoted by a logic 1 or a logic 0. To access the stored information, a component of the device may read, or sense, at least one stored state in the memory device. To store information, a component of the device may write, or program, the state in the memory device.

Various types of memory devices exist, including those that employ magnetic hard disks, random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory, such as PCM and FeRAM, may maintain stored logic states for extended periods of time even in the absence of an external power source. Volatile memory devices, such as DRAM, may lose stored logic states over time unless they are periodically refreshed by a power source. In some cases, non-volatile memory may use similar device architectures as volatile memory but may have non-volatile properties by employing such physical phenomena as ferroelectric capacitance or different material phases.

Improvement of memory devices may include, for example, increasing memory cell density, increasing read/write speeds, increasing reliability, increasing data retention, reducing power consumption, and/or reducing manufacturing costs. To improve overall performance of a memory device, there is a need for increasing the read/write speed while ensuring or increasing reliability of the memory device by mitigating disturbances to memory cells caused by signals in control lines.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example of a memory device, according to the present subject matter.

FIG. 2 illustrates an example of a circuit for memory access in a memory device, such as the memory device of FIG. 1, according to the present subject matter.

FIGS. 3A and 3B illustrate examples of non-linear electrical properties with hysteresis plots for a ferroelectric memory cell, such as a ferroelectric memory cell in the memory device of FIG. 1, with FIG. 3A corresponding to a writing process and FIG. 3B corresponding to a reading process, according to the present subject matter.

FIG. 4 illustrates an example of portions of a memory device, according to the present subject matter.

FIG. 5 illustrates an example of portions of a sense amplifier in a memory device such as the memory device of FIG. 4, according to the present subject matter.

FIG. 6 illustrates an example of a timing diagram for sensing in a memory device such as the memory device of FIG. 4, according to the present subject matter.

FIG. 7 illustrates an example of various scenarios of signal patterns in adjacent digit lines in a memory device such as the memory device of FIG. 4, according to the present subject matter.

FIG. 8 illustrates an example of an output stage of a sense amplifier such as the sense amplifier of FIG. 5, according to the present subject matter.

FIG. 9 illustrates an example of output stages of sense amplifiers, such as the output stages of FIG. 8, connected with each other for controlling a signal slew rate in a digit line, according to the present subject matter.

FIG. 10 illustrates another example of a timing diagram for sensing in a memory device such as the memory device of FIG. 4, according to the present subject matter.

FIG. 11 illustrates another example of an output stage of a sense amplifier such as the sense amplifier of FIG. 5, according to the present subject matter.

FIG. 12 illustrates an example of output stages of sense amplifiers, such as the output stages of FIG. 11, connected with each other for controlling a signal slew rate in a digit line, according to the present subject matter.

FIG. 13 illustrates another example of an output stage of a sense amplifier such as the sense amplifier of FIG. 5, according to the present subject matter.

FIG. 14 illustrates an example of output stages of sense amplifiers, such as the output stages of FIG. 13, connected with each other for controlling a signal slew rate in a digit line, according to the present subject matter.

FIG. 15 illustrates an example of a method for controlling a signal slew rate in a digit line, according to the present subject matter.

FIG. 16 illustrates a block diagram of an example machine with which, in which, or by which any one or more of the techniques discussed herein can be implemented.

### DETAILED DESCRIPTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural, logical and electrical changes may be made without departing from the spirit and scope of the present invention. References to “an”, “one”, or “various” embodiments in this disclosure are not necessarily to the same embodiment, and such references contemplate more than one embodiment. The following detailed description provides examples, and the scope of the present invention is defined by the appended claims and their legal equivalents.

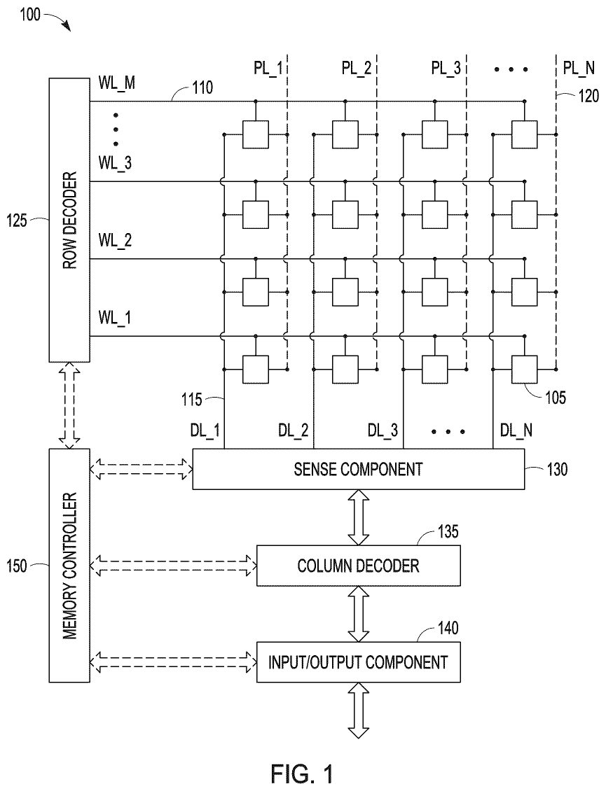

The present disclosure discusses, among other things, a circuit and method for reducing memory cell disturbances by controlling digit line slew rate. Signals in digit lines change when reading from and/or writing into memory cells. Some types of memory, for example ferroelectric random access memory (FeRAM), use two separate operations in the performance of reading or writing functions. These two separate operations can include sensing and programming operations that comprise setting different access lines (e.g., digit lines, plate lines, and word lines) to relatively high or low levels, as discussed with reference to FIG. 1.

FIG. 1 illustrates an example of a memory device 100 according to the present subject matter. Memory device 100 may also be referred to as an electronic memory apparatus. Memory device 100 includes memory cells 105 that are programmable to store different logic states. In some cases, a memory cell 105 may be programmable to store two logic states, denoted a logic 0 (or “low”) and a logic 1 (or “high”). In some cases, a memory cell 105 may be programmable to store more than two logic states.

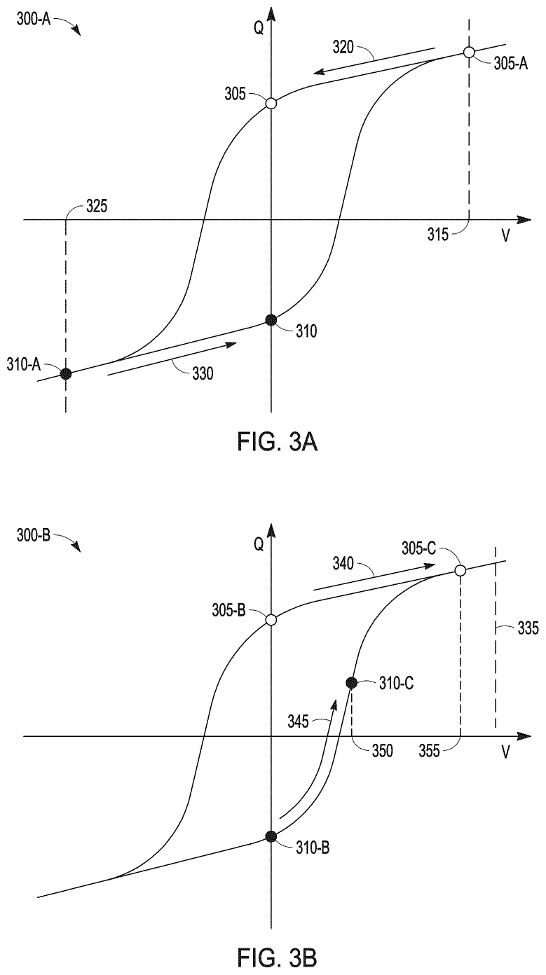

In some examples, a memory cell 105 may store an electrical charge representative of the programmable logic states in a capacitive memory element. For example, a charged and uncharged capacitor of a memory cell 105 may each represent one of two logic states, or a positively charged and a negatively charged capacitor of a memory cell 105 may each represent one of the two logic states. DRAM architectures may commonly use such a design, and the capacitor employed may include a dielectric material with linear or para-electric electric polarization properties as the insulator. In some examples, such as FeRAM architectures, a memory cell 105 may include a ferroelectric capacitor having a ferroelectric material as an insulating layer between terminals of the capacitor. Different levels of polarization of a ferroelectric capacitor may represent different logic states (e.g., supporting two or more logic states in a respective memory cell 105). Ferroelectric materials have non-linear polarization properties including those discussed in further detail below with reference to FIG. 3A and FIG. 3B.

In the example illustrated in FIG. 1, each row of memory cells 105 is coupled with one of a plurality of first access lines 110 (e.g., M word lines, WL_1, WL_2, WL_3, . . . and WL_M, as shown in FIG. 1, also referred to as row lines), and each column of memory cells 105 is coupled with one of a plurality of second access lines 115 (e.g., N digit lines, DL_1, DL_2, DL_3, . . . and DL_N, as shown in FIG. 1, also referred to as bit lines or column lines). Thus, each memory cell 105 may be located at the intersection of one of first access lines 110 and one of second access lines 115. This intersection may be referred to as an address of that memory cell 105. In some cases, first access lines 110 and second access lines 115 may be substantially perpendicular to one another in memory device 100. References to digit lines and bit lines, or their analogues, are interchangeable without loss of understanding or operation. A memory cell 105 targeted to be accessed may be referred to as targeted memory cell 105 and located at the intersection of an energized or otherwise selected access line 110 and an energized or otherwise selected access line 115. In other words, an access line 110 and an access line 115 may be energized or otherwise selected to access (e.g., read from or write into) a memory cell 105 at their intersection. Other memory cells 105 that are in electronic communication with (e.g., connected to) the same access line 110 or 115 may be referred to as untargeted memory cells 105.

Although the access lines discussed with reference to FIG. 1 are shown as direct lines between memory cells 105 and coupled components, access lines may include other circuit elements, such as capacitors, resistors, transistors, amplifiers, voltage sources, switching components, selection components, and others, which may be used to support access operations including those discussed herein. In some examples, an electrode may be coupled with (e.g., between) a memory cell 105 and an access line 110, or with (e.g., between) a memory cell 105 and an access line 115. The term electrode may refer to an electrical conductor, or other electrical interface between components, and in some cases, may be employed as an electrical contact to a memory cell 105. An electrode may include a trace, wire, conductive line, conductive layer, conductive pad, or the like, that provides a conductive path between elements or components of memory device 100.

In some architectures, the component storing the logic state (e.g., a capacitive memory element) of a memory cell 105 may be electrically isolated from a second access line 115 by a selection component. A first access line 110 may be coupled with and may control the selection component. For example, the selection component may be a transistor and first access line 110 may be coupled with a gate of the transistor. Activating first access line 110 may result in an electrical connection or closed circuit between the component storing the logic state of memory cell 105 and its corresponding second access line 115. The second access line 115 may then be accessed to read and/or write the memory cell 105.

In some examples, memory cells 105 may also be coupled with one of a plurality of third access lines 120 (e.g., N plate lines, PL_1, PL_2, PL_3, . . . and PL_N, as shown in FIG. 1). In some examples, the plurality of third access lines 120 may couple memory cells 105 with a voltage source for various reading and/or writing operations including those discussed herein. For example, when a memory cell 105 employs a capacitor for storing a logic state, a second access line 115 may provide access to a first terminal of the capacitor, and a third access line 120 may provide access to a second terminal of the capacitor. As used herein, the term “terminal” need not suggest a physical boundary or connection point of a capacitor of a memory cell 105. Rather, “terminal” may refer to a reference point of a circuit relevant to the capacitor of the memory cell, which may also be referred to as a “node” or “reference point.” Although the plurality of third access lines 120 of the memory device 100 are shown as substantially parallel with the plurality of second access lines 115, in other examples a plurality of third access lines 120 may be substantially parallel with the plurality of first access lines 110, or in any other configuration.

Access operations such as reading, writing, and rewriting may be performed on a memory cell 105 by activating or selecting a first access line 110, a second access line 115, and/or a third access line 120 coupled with the memory cell 105, which may include applying a voltage, a charge, and/or a current to the respective access line. Access lines 110, 115, and 120 may be made of conductive materials, such as metals (e.g., copper (Cu), silver (Ag), aluminum (Al), gold (Au), tungsten (W), titanium (Ti), etc.), metal alloys, carbon, or other conductive materials, alloys, or compounds. Upon selecting a memory cell 105, a resulting signal may be used to determine the stored logic state. For example, a memory cell 105 with a capacitive memory element storing a logic state may be selected, and the resulting flow of charge via an access line and/or resulting voltage of an access line may be detected to determine the programmed logic state of the memory cell 105.

Access to memory cells 105 may be controlled through a row decoder 125 and a column decoder 135. For example, a row decoder 125 may receive a row address from a memory controller 150 and activate the appropriate first access line 110 based on the received row address. Similarly, a column decoder 135 may receive a column address from memory controller 150 and activate the appropriate second access line 115 based on the received column address. Thus, in some examples a memory cell 105 may be accessed by activating a first access line 110 and a second access line 115.

In some examples, memory controller 150 may control the operations (e.g., read operations, write operations, rewrite operations, and refresh operations, discharge operations) of memory cells 105 through the various components (e.g., row decoder 125, column decoder 135, and a sense component 130). In some cases, one or more of the row decoder 125, column decoder 135, and sense component 130 may be co-located or otherwise included with memory controller 150. Memory controller 150 may generate row and column address signals to activate a desired first access line 110 and second access line 115. Memory controller 150 may also generate or control various voltages or currents used during the operation of memory device 100. For example, memory controller 150 may apply a discharge voltage to a first access line 110 or a second access line 115 after accessing one or more memory cells 105.

In general, the amplitude, shape, or duration of an applied voltage, current, or charge may be adjusted or varied, and may be different for the various operations discussed in operating memory device 100. Further, one, multiple, or all memory cells 105 within memory device 100 may be accessed simultaneously. For example, multiple or all memory cells 105 of memory device 100 may be accessed simultaneously during a reset operation in which all memory cells 105, or a group of memory cells 105, are set to a single logic state.

A memory cell 105 may be read, or sensed, by a sense component 130. For example, sense component 130 may be configured to determine the stored logic state of a memory cell 105 based on a signal generated by accessing that memory cell 105. The signal may include a voltage, an electrical charge, an electrical current, or a combination thereof, and sense component 130 may include voltage sense amplifiers, charge sense amplifiers, current sense amplifiers, or a combination of two or more of such amplifiers.

In some examples, a threshold current may be defined for sensing the logic state stored by a memory cell 105. The threshold current may be set above a current that may pass through that memory cell 105 in response to a read signal when that memory cell 105 stores a first logic state, but equal to or below an expected current through that memory cell 105 in response to the read signal when that memory cell 105 stores a second logic state. For example, the threshold current may be higher than a leakage current of the associated access lines 110 or 115. In some examples, a logic state stored by a memory cell 105 may be determined based on a voltage (e.g., across a shunt resistance) resulting from the current driven by a read pulse. For example, the resulting voltage may be compared to a reference voltage, with a first logic state being detected when the resulting voltage is less than the reference voltage and a second logic state detected when the resulting voltage is greater than the reference voltage.

Sense component 130 may include various switching components, selection components, transistors, amplifiers, capacitors, resistors, or voltage sources to detect and amplify a difference in sensing signals (e.g., a difference between a read voltage and a reference voltage, a difference between a read current and a reference current, or a difference between a read charge and a reference charge), aspects of which, in some examples, may be referred to as latching. In some examples, sense component 130 may include a collection of components (e.g., circuit elements) that may be repeated for each of a set of access lines 115 connected to the sense component 130. For example, sense component 130 may include a separate sensing circuit (e.g., a separate sense amplifier, or a separate signal development circuit) for each of a set of access lines 115 coupled with the sense component 130, such that a logic state may be separately detected for a respective memory cell 105 coupled with a respective one of the set of access lines 115. In various examples, a reference signal source or generated reference signal may be shared between components of memory device 100 (e.g., shared among one or more components of sense components 130, such as separate sensing circuits of sense component 130).

Sense component 130 may be included in a device that includes memory device 100. For example, sense component 130 may be included with other read and write circuits, decoding circuits, or register circuits of the memory that may be coupled to memory device 100. In some examples, the detected logic state of a memory cell 105 may be output through a column decoder 135 as an output. In some examples, sense component 130 may be part of column decoder 135 or row decoder 125. In some examples, sense component 130 may be connected to or otherwise in electronic communication with column decoder 135 or row decoder 125.

Although a single sense component 130 is shown, memory device 100 may include more than one sense component 130. For example, a first sense component 130 may be coupled with a first subset of access lines 115 and a second sense component 130 may be coupled with a second subset of access lines 115 (e.g., different from the first subset of access lines 115). In some examples, such a division of sense components 130 may support parallel (e.g., simultaneous) operation of multiple sense components 130. In some examples, such a division of sense components 130 may support matching sense components 130 having different configurations or characteristics to particular subsets of the memory cells 105 of the memory device (e.g., supporting different types of memory cells 105, supporting different characteristics of subsets of memory cells 105, and/or supporting different characteristics of subsets of access lines 115). Additionally or alternatively, two or more sense components 130 may be coupled with the same set of access lines 115 (e.g., for component redundancy). In some examples, such a configuration may support maintaining functionality to overcome a failure or otherwise poor operation of one of the redundant sense components 130. In some examples, such a configuration may support the ability to select one of the redundant sense components 130 for particular operational characteristics (e.g., as related to power consumption characteristics and/or as related to access speed characteristics for a particular sensing operation).

In ferroelectric memory architectures, accessing a memory cell 105 may degrade or destroy the stored logic state, and rewrite or refresh operations may be performed to return the original logic state to that memory cell 105. In DRAM or FeRAM, for example, a capacitor of a memory cell 105 may be partially or completely discharged during a sense operation, thereby corrupting the logic state that was stored in that memory cell 105. Thus, in some examples, the logic state stored in a memory cell 105 may be rewritten after an access operation. Further, activating a single access line 110 or 115 may result in the discharge of all memory cells 105 coupled with the access line 110 or 115. Thus, several or all memory cells 105 coupled with an access line 110 or 115 of an access operation (e.g., all cells of an accessed row, all cells of an accessed column) may be rewritten after the access operation.

A ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., by grounding or virtually grounding the ferroelectric memory element).

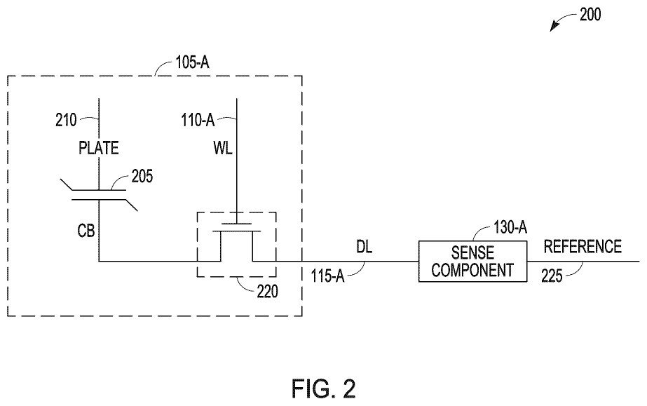

FIG. 2 illustrates an example of a circuit 200 for memory access in a memory device, such as memory device 100, according to the present subject matter. Circuit 200 may include a ferroelectric memory cell 105-A, a word line 110-A (“WL” as shown in FIG. 2), a digit line 115-A (“DL” shown in FIG. 2), and a sense component 130-A, which may respectively be an example of memory cells 105, an example of access lines 110, an example of access lines 115, and an example of sense component 130 or a portion thereof. Circuit 200 includes a logic storage component, such as a capacitor 205 that includes two conductive terminals, a cell plate 210 (“Plate” as shown in FIG. 2) and a cell bottom 215 (“CB” as shown in FIG. 2). These terminals may be separated by an insulating ferroelectric material. As discussed above, various logic states may be stored by charging or discharging capacitor 205. Cell plate 210 may correspond to an example of plate lines 120 and therefore may also be referred to as plate line 210.

The stored logic state of capacitor 205 may be read, or sensed, by operating various elements of circuit 200. Capacitor 205 may be in electronic communication with digit line 115-A. Capacitor 205 may be isolated from the digit line 115-A when selection component 220 is deactivated, and capacitor 205 may be connected to digit line 115-A via selection component 220 when selection component 220 is activated. In some cases, selection component 220 may be a transistor and its operation may be controlled by applying a voltage to the transistor gate through word line 110-A, with the magnitude of the applied voltage being greater than the threshold magnitude of the transistor. For example, a voltage applied to word line 110-A and hence the transistor gate may activate selection component 220, thereby connecting capacitor 205 with digit line 115-A.

In some examples, capacitor 205 is a ferroelectric capacitor. The change in stored charge depends on the initial state of capacitor 205, i.e., whether the initial state corresponds to a logic 1 or a logic 0. The change in charge stored in capacitor 205 may then be compared to a reference (e.g., a reference voltage) by sense component 130-A in order to determine the logic state stored in memory cell 105-A. To write memory cell 105-A, a voltage may be applied across capacitor 205.

FIG. 3A and FIG. 3B illustrate examples of non-linear electrical properties with hysteresis plots for a ferroelectric memory cell in a memory device, such as memory device 100, according to the present subject matter. Hysteresis curves 300-A, shown in FIG. 3A, and 300-B, shown in FIG. B, illustrate an example of writing and reading process, respectively, for a ferroelectric memory cell, such as memory cell 105-A. Hysteresis curves 300 depict the charge, Q, stored on a ferroelectric capacitor, such as capacitor 205, as a function of a voltage difference, V, applied on the ferroelectric capacitor.

A ferroelectric material is characterized by a spontaneous electric polarization. For example, the ferroelectric material maintains a non-zero electric polarization in the absence of an electric field. Examples of the ferroelectric material include barium titanate (BaTiO3), lead titanate (PbTiO3), lead zirconium titanate (PZT), and strontium bismuth tantalate (SBT). The ferroelectric capacitors described herein may include these or other ferroelectric materials. Electric polarization within a ferroelectric capacitor results in a net charge at the ferroelectric material's surface and attracts opposite charge through the capacitor terminals. Thus, charge is stored at the interface of the ferroelectric material and the capacitor terminals. Because the electric polarization may be maintained in the absence of an externally applied electric field for relatively long times, charge leakage may be significantly decreased as compared with, for example, capacitors employed in volatile memory arrays. This may reduce the need to perform refresh operations as described above for some volatile memory architectures.

Hysteresis curves 300 may be understood from the perspective of a single terminal of a capacitor. By way of example, if the ferroelectric material has a negative polarization, positive charge accumulates at the terminal. Likewise, if the ferroelectric material has a positive polarization, negative charge accumulates at the terminal. Additionally, it should be understood that the voltages in hysteresis curves 300 represent a voltage difference across the capacitor and are directional. For example, a positive voltage may be realized by applying a positive voltage to the terminal and maintaining the other terminal at ground (or approximately 0 V). A negative voltage may be applied by maintaining the terminal at ground and applying a positive voltage to the other terminal. Similarly, two positive voltages, two negative voltages, or any combination of positive and negative voltages may be applied to the appropriate capacitor terminals to generate the voltage difference shown in hysteresis curves 300.

As shown in hysteresis curve 300-A, the ferroelectric material may maintain a positive or negative polarization with a zero-voltage difference, resulting in two possible charged states: charge state 305-A and charge state 310-A. In the example of FIG. 3A, charge state 305 represents a logic 0 and charge state 310 represents a logic 1. In some examples, the logic values of the respective charge states may be reversed without loss of understanding.

A logic 0 or 1 may be written to the memory cell by controlling the electric polarization of the ferroelectric material, and thus the charge on the capacitor terminals, by applying a voltage. For example, applying a net positive voltage 315 across the capacitor results in charge accumulation until charge state 305-A is reached. Upon removing voltage 315, charge state 305-A follows path 320 until it reaches charge state 305 at zero voltage potential. Similarly, charge state 310 is written by applying a net negative voltage 325, which results in charge state 310-A. After removing negative voltage 325, charge state 310-A follows path 330 until it reaches charge state 310 at zero voltage. In some example aspects, after sensing, stored data in a cell is destroyed (e.g., written to “0” regardless of the original data). Accordingly, if a “0” is to be programmed into the cell, no further action is needed. However, if a “1” is to be programmed into the cell, then writing a “1” as described above may occur.

To read, or sense, the stored state of the ferroelectric capacitor, a voltage may be applied across the capacitor. In response, the stored charge changes, and the degree of the change depends on the initial charge state, i.e., the degree to which the stored charge of the capacitor changes varies depending on whether charge state 305-B or 310-B was initially stored. For example, hysteresis curve 300-B illustrates two possible stored charge states 305-B and 310-B. Net voltage 335 may be applied across the capacitor. Although depicted as a positive voltage, voltage 335 may be negative. In response to voltage 335, charge state 305-B may follow path 340. Likewise, if charge state 310-B was initially stored, then it follows path 345. The final position of charge state 305-C and charge state 310-C depend on a number of factors, including the specific sensing operation and circuitry.

In some cases, the final charge may depend on the intrinsic capacitance of the digit line of a memory cell. For example, if the capacitor is electrically connected to the digit line and voltage 335 is applied, the voltage of the digit line may rise due to its intrinsic capacitance. Therefore, a voltage measured at a sense component may not equal voltage 335 and instead may depend on the voltage of the digit line. The position of final charge states 305-C and 310-C on hysteresis curve 300-B may thus depend on the capacitance of the digit line and may be determined through a load-line analysis, i.e., charge states 305-C and 310-C may be defined with respect to the digit line capacitance. As a result, the voltage of the capacitor, voltage 350 or voltage 355, may be different and may depend on the initial state of the capacitor. By comparing voltage 350 or voltage 355 to a reference voltage, the initial state of the capacitor may be determined. For example, the reference voltage may be an average of voltage 350 and 355 and, upon comparison, the sensed voltage may be determined to be higher or lower than the reference voltage. A value of the ferroelectric cell (i.e., a logic 0 or 1) may then be determined based on the comparison.

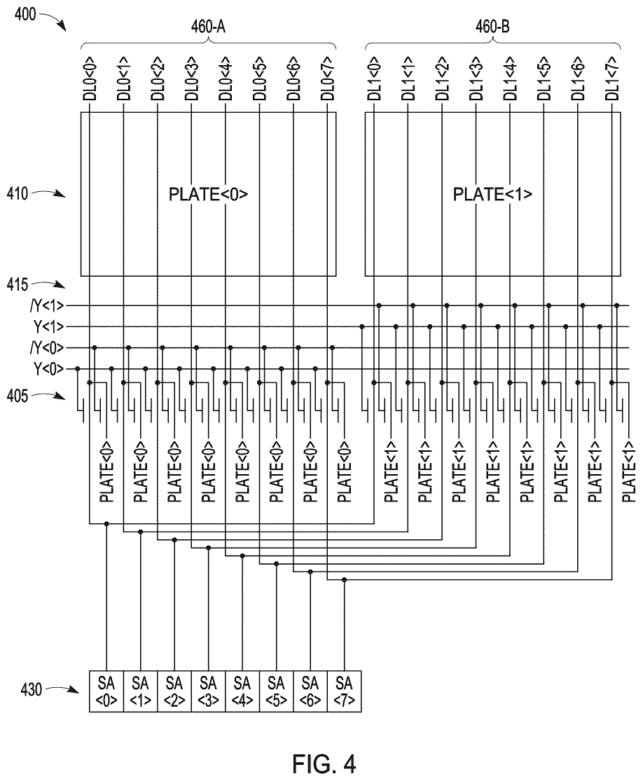

FIG. 4 illustrates an example of portions of a memory device 400, according to the present subject matter. The portions of memory device 400 as shown in FIG. 4 include multiple plates (PLs) 410, multiple digit lines (DLs) 415; multiple memory cells 405, and multiple sensing amplifiers (SAs) 430. In the illustrated example, these elements of memory device 400 are arranged according to an array architecture that include multiple plate groups 460, with plate groups 460-A and 460-B shown as examples. Memory device 400 may include any number of such plate groups. Plate groups 460 may each include a particular plate of multiple plates 410, a memory cell group including memory cells of memory cells 405 that are coupled to the plate, a digit line group including digit lines of digital lines 415 that are respectively coupled to the memory cells, and a sense amplifier group including sense amplifiers of sense amplifiers 430 that are respectively coupled to the memory cells through the digit lines.

For example, plate group 460-A may include the memory cell group of 8 memory cells of memory cells 405 coupled to a plate<0> and coupled to respective sense amplifiers SA<0>-<7> of the sense amplifier group through respective digit lines DL0<0>-<7> of the digit line group. The 8 memory cells may include capacitive elements and respective selection components, such as illustrated by memory cell 105-A in FIG. 2. The capacitive elements may each be a ferroelectric capacitor and may be coupled to plate<0> directly and coupled to respective digit lines DL0<0>-<7> through the respective selection components. The selection component may be driven by complementary selection lines Y<0> and/Y<0>, which may be driven by one or more word lines of memory device 400. Similarly, plate group 460-B may include the memory cell group of 8 memory cells of memory cells 405 coupled to a plate<1> and coupled to respective sense amplifiers SA<0>-<7> of the sense amplifier group through respective digit lines DL1<0>-<7> of the digit line group. The 8 memory cells may include capacitive elements and respective selection components, such illustrated by memory cell 105-A in FIG. 2. The capacitive elements may each be a ferroelectric capacitor and may be coupled to plate<1> directly and coupled to respective digit lines DL1<0>-<7> through the respective selection components. The selection component may be driven by complementary selection lines Y<1> and/Y<1>, which may be driven by one or more word lines of memory device 400. Plate groups including, but not being limited to, plate groups 460-A and 460-B may share the sense amplifier group including SA<0>-<7>.

Thus, all the digit lines corresponding to a selected plate are connected to respective sense amplifiers. An example of such an array architecture of a memory device is discussed in U.S. Patent Application Publication No., 2021/0142862 A1, assigned to Micron Technology, Inc., which is incorporated herein by reference in its entirety.

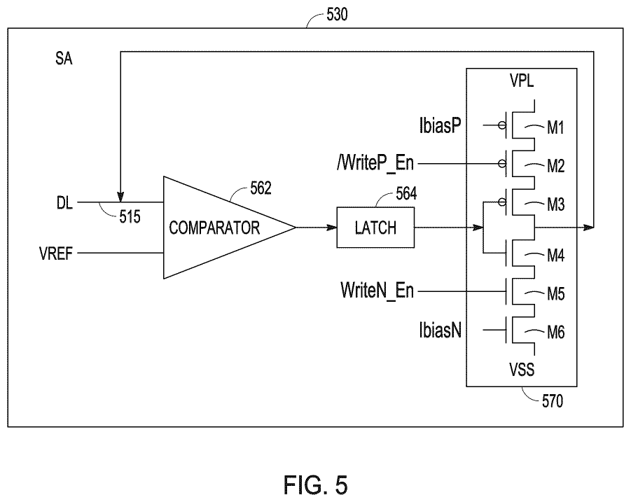

FIG. 5 illustrates an example of portions of a sense amplifier (SA) 530 in a memory device such as memory device 400, according to the present subject matter. Sense amplifier 530 may represent an example of each of sense amplifiers 430. Sense amplifier 530 may be coupled to a digit line (DL) 515 and may include a comparator 562, a latch 564, and an output stage 570. Comparator 562 may receive a signal indicative of a logic state stored in the memory cell coupled to digit line 515, receive a reference voltage (VREF), and compare the amplitude of the signal to the reference voltage to produce a comparator output indicative of the logic state. Latch 564 may latch the comparator output to drive output stage 570. Output stage 570 may produce an output signal driving digit line 515.

In the illustrated example, output stage 570 includes PMOS transistors (p-channel metal-oxide-semiconductor field-effect transistors) M1, M2, and M3 and NMOS transistors (n-channel metal-oxide-semiconductor field-effect transistors) M4, M5, and M6. M1 and M6 may receive complementary biasing signals, IbiasP and IbiasN, respectively. When sense amplifiers 430 each include sense amplifier 530, the bias currents, IbiasP and IbiasN, are each shared by all the sense amplifiers of a sense amplifier group (e.g., SA<0>-<7>). M2 and M5 may receive complementary write enabling signals, /WriteP_En and WrtieN_En, respectively, that enable the application of the output signal on digit line 515. M3 and M4 are driven by the output of latch 564 that indicates the logic state. M1 and M6 may have characteristics selected for determining the slew rate (i.e., rate of rising or falling) of the output signal produced by output stage 570. M1 and M6 may each also represent multiple transistors connected in parallel for increasing the slew rate of the output signal.

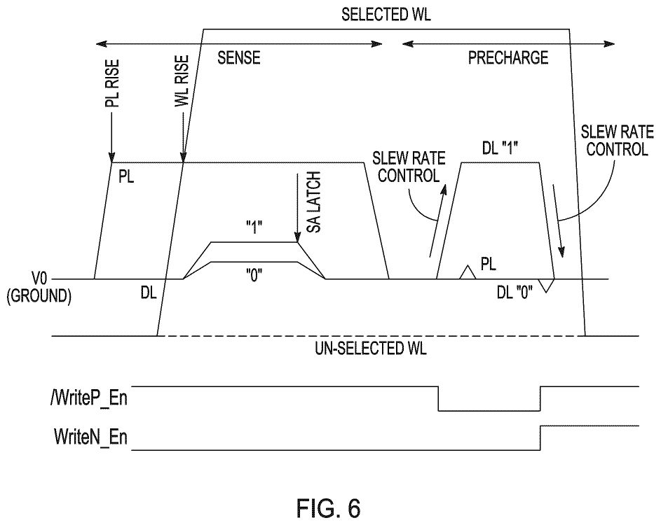

FIG. 6 illustrates an example of a timing diagram for sensing in a memory device such as memory device 400, according to the present subject matter. An access operation performed on a selected ferroelectric memory cell includes two phases: a sensing phase (during which a voltage difference is applied to the capacitive component, the logic state of the memory cell is sensed, and written back if applicable) and a precharge phase (during which the voltage difference returns to zero, and the memory cell returns to a stable logic state), as illustrated in FIG. 3B.

Digit line low (DL=L) sensing is the case illustrated in FIG. 6. During the sensing phase, the plate (PL) rises from V0 (ground, or 0 V) (e.g., to 1.0 V) and returns to V0, the selected word line (WL) rises (e.g., from −0.2 V to 3.0 V), and the digit line (DL) rises from V0 (e.g., to 0.2 V if DL=1, or to 0.1 V if DL=0) and returns to V0 after the sense amplifier latches (SA latch). During the precharge phase, the plate (PL) stays at V0, the selected word line falls (e.g., from 3.0 V to −0.2 V), and the digit line (DL) rises from V0 (e.g., to 1.0 V) if DL=1, or stays at V0 if DL=0.

In memory device 400, the digit lines of a digit line group may each be positioned directly adjacent to one or more other digit lines of the digit line group. Consequently, each digital line of the digit line group may be disturbed by a signal in each directly adjacent digit line of the digit line group. As shown in FIG. 6, during the precharge phase, the plate is stable, but each grounded digit line (DL=L) may have glitches due to the cross coupling between the adjacent digit lines. The glitches may result in disturbance of the memory cell coupled to that grounded digit line. During the pre-charge phase, slew rate in a digit line may be controlled to limit the magnitude of the glitches, thereby mitigating disturbance of the memory cells connected to the adjacent digit lines caused by cross coupling between these digit lines. However, controlling the slew rate may limit the speed of access to the memory cells.

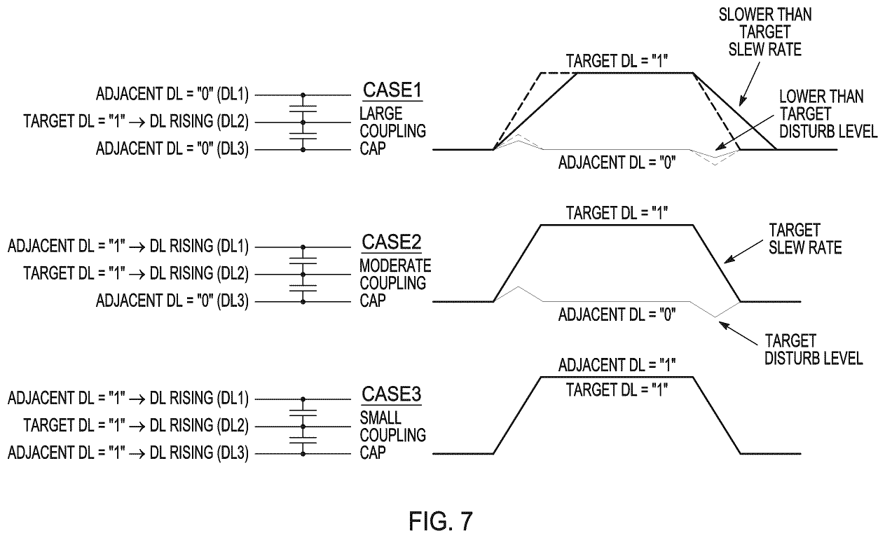

FIG. 7 illustrates an example of various scenarios of signal patterns in adjacent digit lines in a memory device such as memory device 400, according to the present subject matter. Shown in FIG. 7 are three cases with a target digit line (the aggressor digit line for which the slew rate is to be controlled) and two adjacent digit lines, during the precharge phase. For purposes of illustration and discussion, DL2 refers to the target digit line, and DL1 and DL3 each refer to an adjacent digit line that is directly adjacent to DL2.

In Case 1, DL1=0 (grounded), target DL2=1 (rising), and adjacent DL3=0 (grounded). Case 1 results in a relatively large cross coupling capacitance. In Case 2, adjacent DL1=1 (rising), target DL2=1 (rising), and adjacent DL3=0 (grounded). Case 2 results in a relatively moderate cross coupling capacitance. In Case 3, adjacent DL1=1 (rising), target DL2=1 (rising), and adjacent DL3=1 (rising). Case 3 results in a relatively small cross coupling capacitance.

Case 3 is not a problem because signals in all three digit lines rise and fall together such that no disturbance occurs. Case 2 is the worst case for disturbance. Because the target DL2 and the adjacent DL1 rise and fall together, the cross coupling capacitance between DL1 and DL2 is cancelled, making the rising speed in the target DL2 quicker, resulting in a strong disturbance to the grounded adjacent DL3. The slew rate of the target DL2 may be controlled to remain under a limit above which the glitches in the adjacent DL3 is intolerable. In other words, the disturbance is controlled by setting the slew rate in the target DL2 to a target slew rate to address the worst case for disturbance. The target slew rate is a maximum slew rate set for limiting the magnitude of the glitches in Case 2. In Case 1, because the target DL2 and both of the adjacent DL1 and DL3 are grounded, the overall cross coupling capacitance is the largest, resulting in a slew rate in the target DL2 that is slower than the target slew rate (e.g., a slew rate that is set for the worst case of Case 2). Consequently, while Case 1 is not a problem in terms of disturbance, the slower slew rate limits the speed of access to the memory cells. In other words, referring back to FIG. 5, when output stage 570 of sense amplifier 530 is configured commonly for all three cases to set the slew rate of the output signal (driving digit line DL 515) to guarantee data accuracy under the worst case for disturbance, the slew rate in digit line 515 is lower than necessary in terms of disturbance under Case 1, thereby limiting the speed of the memory device.

The present subject matter provides for control of the slew rate in the target DL2 in Case 1 that differs from the control in Case 2 to increase the rising and falling speeds of a signal in the target DL2 while guaranteeing the performance of the memory device in Case 2. The slew rate in the target digit line may be increased while the amplitude of the glitches in the adjacent digit line(s) does not exceed the limit.

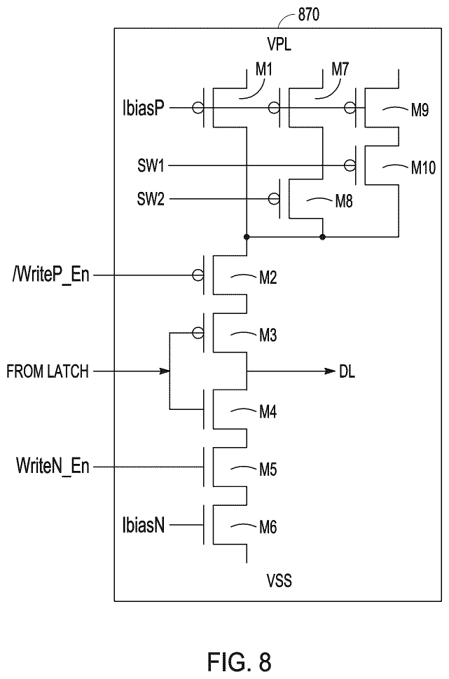

FIG. 8 illustrates an example of an output stage 870 of a sense amplifier such as sense amplifier 530, according to the present subject matter. Output stage 870 may represent an example of output stage 570 with one or more additional biasing devices connected in parallel with biasing device M1 for use during digit line low (DL=L) sensing. In the illustrated example, output stage 870 includes a first additional biasing device M7, which may be activated using a switching signal SW2 driving a switching device M8, and a second additional biasing device M9, which may be activated using a switching signal SW1 driving a switching device M10. Thus, for digit line low (DL=L) sensing, the output signal driving digit line 515 may be controlled by switching signals SW1 and SW2, in addition to biasing signal IbiasP.

In the illustrated example, M7, M8, M9, and M10 are each a PMOS transistor. Biasing devices M7 and M9 may each include a PMOS transistor having characteristics chosen for a desirable slew rate and/or multiple PMOS transistors connected in parallel with the number of transistors determined for the desirable slew rate.

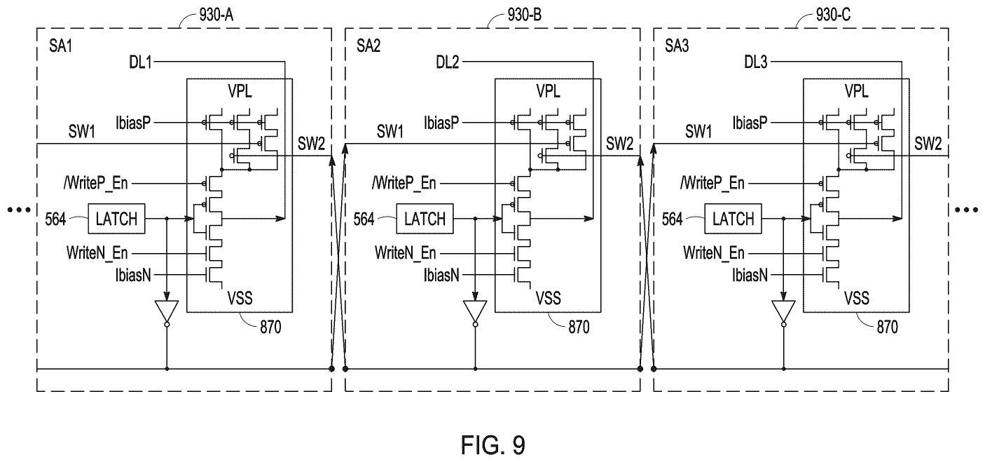

FIG. 9 illustrates an example of output stages 870 of sense amplifiers 930 connected with each other for controlling the slew rate in the digit lines during digit line low (DL=L) sensing, according to the present subject matter. Sense amplifiers 930 may represent an example of sense amplifier 530 with output stage 870 (instead of output stage 570). For purposes of illustration and discussion, FIG. 9 shows three sensing amplifiers: sense amplifier 930-A (or SA1), sense amplifier 930-B (or SA2), and sense amplifier 930-C (or SA3), which are coupled to digital lines DL1, DL2, and DL3, respectively. Digit lines DL1, DL2, and DL3 in FIG. 9 may correspond to digit lines DL1, DL2, and DL3 in FIG. 7, respectively. Thus, digit lines DL1 and DL3 are each directly adjacent to digit line DL2. For each sense amplifier coupled to a target digit line, an “adjacent sense amplifier” refers to another sense amplifier coupled to an adjacent digit line. For example, SA1 and SA3 are each an adjacent sense amplifier of SA2.

As illustrated in FIG. 9, each sense amplifier of sense amplifiers 930 receives a switching signal from an adjacent sense amplifier. The switching signal may be a signal indicative of a logic state of the adjacent digit line driven by the output of the adjacent sense amplifier. In the illustrated example, the switch signal is inverted from the input signal to output stage 870 of the adjacent sense amplifier. For example, for SA2, switch signal SW1 is received from the input to output stage 870 of SA1 through an inverter, and switch signal SW2 is received from the input to output stage 870 of SA3 through an inverter. In such a manner, the slew rate for the target digit line is controlled by the signal pattern in the target and adjacent digit lines. Various signal patterns are discussed under Cases 1-3 above. The connections between sense amplifiers as illustrated in FIG. 9 strengthens the output current from output stage 870 in Case 1 to increase the slew rate in the target digit line (e.g., moving the Target DL curve from the solid curve to the dotted curve) while ensuring that the resulting glitches in the adjacent digit lines does not exceed the limit set for avoiding disturbances.

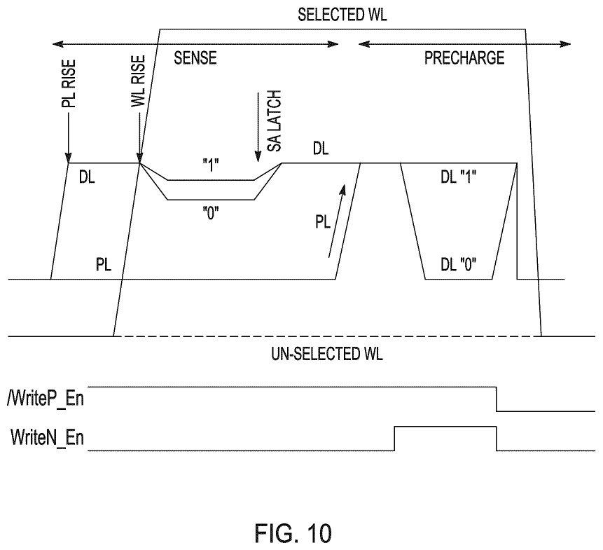

FIG. 10 illustrates another example of a timing diagram for sensing in a memory device such as memory device 400, according to the present subject matter. Digit line high (DL=H) sensing is the case illustrated in FIG. 10. During the sensing phase, the plate (PL) rises from V0 (ground, or 0 V) (e.g., to 1.0 V) at the end of the phase, the selected word line (WL) rises (e.g., from −0.2 V to 3.0 V), and the digit line (DL) falls (e.g., from 1.0 V to 0.9 V if DL=1, or from 1.0 V to 0.8 V if DL=0) and returns (e.g., to 1.0 V) after the sense amplifier latches (SA latch). During the precharge phase, the plate (PL) falls (e.g., from 1.0 V) to V0 at the end of the phase, the selected word line falls (e.g., from 3.0 V to −0.2 V) at the end of the phase, and the digit line (DL) falls to V0 (e.g., from 1.0 V) and returns (e.g., to 1.0 V) if DL=0 and stays (e.g., at 1.0 V).

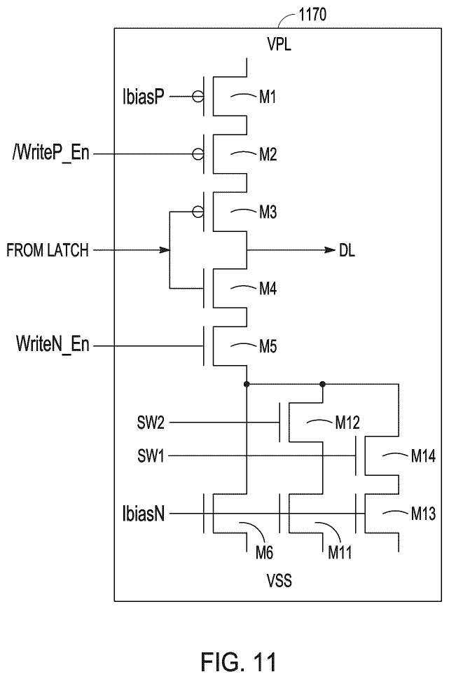

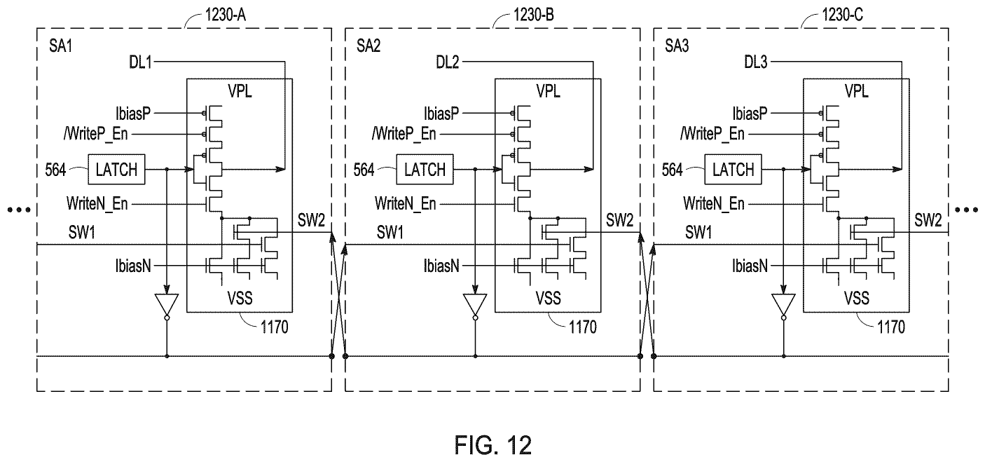

During the precharge phase, the plate is stable, but each non-grounded digit line (DL=H) may have glitches due to the cross coupling between the adjacent digit lines. The glitches may result in disturbance of the memory cell coupled to that grounded digit line. During the pre-charge phase, slew rate in a digit line may be controlled to limit the magnitude of the glitches, thereby mitigating disturbance of the memory cells connected to the adjacent digit lines caused by cross coupling between these digit lines. However, controlling the slew rate may limit the speed of access to the memory cells. As in the case of digit line low (DL=L) sensing, as discussed above with references to FIGS. 6-9, digit line signal patterns as discussed in Cases 1-3 applies, and the present subject matter provides for an approach similar to what is discussed above with reference to FIGS. 8 and 9, which is discussed below with reference to FIGS. 11 and 12

FIG. 11 illustrates an example of an output stage 1170 of a sense amplifier such as sense amplifier 530, according to the present subject matter. Output stage 1170 may represent an example of output stage 570 with one or more additional biasing devices connected in parallel with biasing device M6 for use during digit line high (DL=H) sensing. In the illustrated example, output stage 1170 includes a first additional biasing device M11, which may be activated using a switching signal SW2 driving a switching device M12, and a second additional biasing device M13, which may be activated using a switching signal SW1 driving a switching device M14. Thus, for digit line high (DL=H) sensing, the output signal driving digit line 515 may be controlled by switching signals SW1 and SW2, in addition to biasing signal IbiasN.

In the illustrated example, M11, M12, M13, and M14 are each an NMOS transistor. Biasing devices M11 and M13 may each include an NMOS transistor having characteristics chosen for a desirable slew rate and/or multiple NMOS transistors connected in parallel with the number of transistors determined for the desirable slew rate.

FIG. 12 illustrates an example of output stages 1170 of sense amplifiers 1230 connected with each other for controlling the slew rate in the digit lines during digit line high (DL=H) sensing, according to the present subject matter. Sense amplifiers 1230 may represent an example of sense amplifier 530 with output stage 1170 (instead of output stage 570). For purposes of illustration and discussion, FIG. 12 shows three sensing amplifiers: sense amplifier 1230-A (or SA1), sense amplifier 1230-B (or SA2), and sense amplifier 1230-C (or SA3), which are coupled to digital lines DL1, DL2, and DL3, respectively. DL1, DL2, and DL3 in FIG. 12 may correspond to digit lines DL1, DL2, and DL3 in FIG. 7, respectively. Thus, digit lines DL1 and DL3 are each directly adjacent to digit line DL2. For each sense amplifier coupled to a target digit line, an “adjacent sense amplifier” refers to another sense amplifier coupled to an adjacent digit line. For example, SA1 and SA3 are each an adjacent sense amplifier of SA2.

As illustrated in FIG. 12, each sense amplifier of sense amplifiers 930 receives a switching signal from an adjacent sense amplifier. The switch signal may be a signal indicative of a logic state of the adjacent digit line driven by the output of the adjacent sense amplifier. In the illustrated example, the switch signal is a signal inverted from the input signal to output stage 1170 of the adjacent sense amplifier. For example, for SA2, switch signal SW1 is received from the input to output stage 1170 of SA1 through an inverter, and switch signal SW2 is received from the input to output stage 1170 of SA3 through an inverter. In such a manner, the slew rate for the target digit line is controlled by the signal pattern in the target and adjacent digit lines. Various signal patterns are discussed under Cases 1-3 above. The connections between sense amplifiers as illustrated in FIG. 12 strengthens the output current from output stage 1170 in Case 1 to increase the slew rate in the target digit line (e.g., moving the Target DL curve from the solid curve to the dotted curve) while ensuring that the resulting glitches in the adjacent digit lines does not exceed the limit set for avoiding disturbances.

In some examples, memory device 400 may be configured for both digit line low sensing and digit line high sensing. In such examples, memory device 400 may include both sense amplifiers 930 interconnected as illustrated in FIG. 9 and sense amplifiers 1230 interconnected as illustrated in FIG. 12.

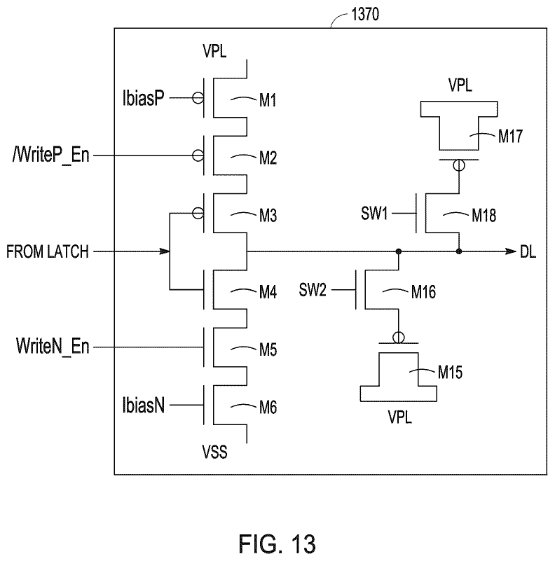

FIG. 13 illustrates an example of an output stage 1370 of a sense amplifier such as sense amplifier 530, according to the present subject matter. Output stage 1370 may represent an example of output stage 570 with one or more decoupling capacitors each coupled to the digit line. In the illustrated example, output stage 1370 includes a first decoupling capacitor M15, which may be activated using a switching signal SW2 driving a switching device M16, and a second decoupling capacitor M17, which may be activated using a switching signal SW1 driving a switching device M18. M15 and M17 are each shown in FIG. 13 as a PMOS capacitor formed by connecting the drain and the source of a PMOS transistor to the plate voltage (VPL) and the gate to switch M16 or M18, respectively. M16 and M18 may each be an NMOS transistor with the gate receiving the switch signals SW2 and SW1, respectively. In other examples, M15 and M17 may each be an NMOS capacitor, a metal-insulator-metal (MIM) capacitor, or another suitable type of capacitor. Decoupling capacitors M15 and M17 may each include a capacitor having a capacitance chosen for a desirable slew rate in the target digit line and/or multiple capacitors connected in parallel with the total capacitance determined for the desirable slew rate.

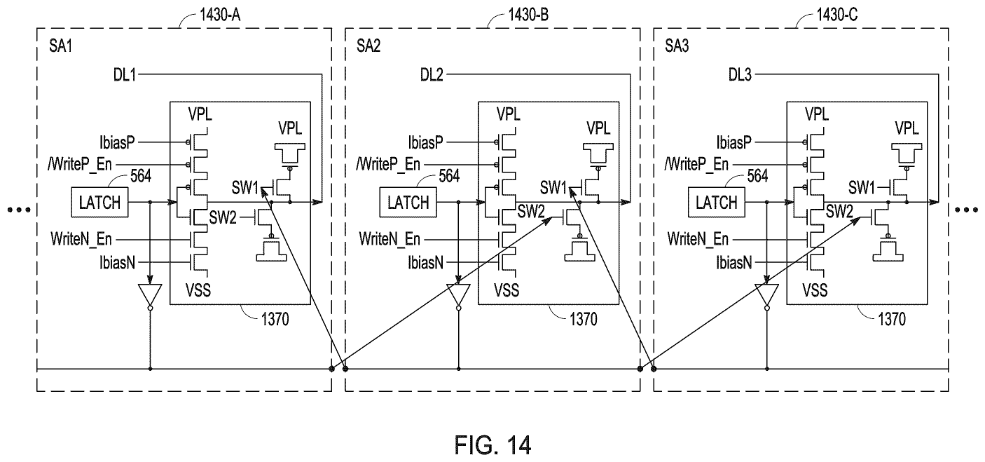

FIG. 14 illustrates an example of output stages 1370 of sense amplifiers 1439 connected with each other for controlling a signal slew rate in a digit line, according to the present subject matter. Sense amplifiers 1430 may represent an example of sense amplifier 530 with output stage 1370 (instead of output stage 570). For purposes of illustration and discussion, FIG. 14 shows three sensing amplifiers: sense amplifier 1430-A (or SA1), sense amplifier 1430-B (or SA2), and sense amplifier 1430-C (or SA3), which are coupled to digital lines DL1, DL2, and DL3, respectively. DL1, DL2, and DL3 in FIG. 14 may correspond to digit lines DL1, DL2, and DL3 in FIG. 7, respectively. Thus, digit lines DL1 and DL3 are each directly adjacent to digit line DL2. For each sense amplifier coupled to a target digit line, an “adjacent sense amplifier” refers to another sense amplifier coupled to an adjacent digit line. For example, SA1 and SA3 are each an adjacent sense amplifier of SA2.

As illustrated in FIG. 14, each sense amplifier of sense amplifiers 930 receives a switching signal from an adjacent sense amplifier. The switch signal may be a signal indicative of a logic state of the adjacent digit line driven by the output of the adjacent sense amplifier. In the illustrated example, the switch signal is a signal inverted from the input signal to output stage 1370 of the adjacent sense amplifier. For example, for SA2, switch signal SW1 is received from the input to output stage 1370 of SA3 through an inverter, and switch signal SW2 is received from the input to output stage 1370 of SA1 through an inverter. In such a manner, the slew rate for the target digit line is controlled by the signal pattern in the target and adjacent digit lines. Various signal patterns are discussed under Cases 1-3 above. The connections between sense amplifiers as illustrated in FIG. 14 strengthens the output current from output stage 1370 in Case 1 to increase the slew rate in the target digit line (e.g., moving the Target DL curve from the solid curve to the dotted curve) while ensuring that the resulting glitches in the adjacent digit lines does not exceed the limit set for avoiding disturbances.

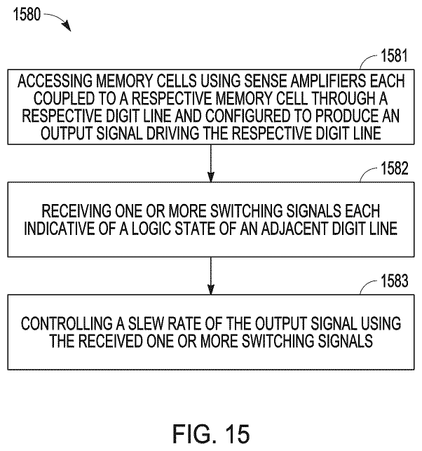

FIG. 15 illustrates an example of a method 1580 for controlling a signal slew rate in a digit line, according to the present subject matter. Method 1580 may be performed to improve performance of a memory device, such as memory device 400, by increasing a speed of memory cell access while ensuring data accuracy by mitigating disturbances.

At operation 1581, memory cells of a memory device are accessed using sense amplifiers coupled to the memory cells through digit lines. The sense amplifiers are each coupled to a respective memory cell of the memory cells through a respective digit line of digit lines and each include an output stage configured to produce an output signal driving the respective digit line. This respective digit line (which may be referred to as “the target digit line”) is directly adjacent to one or more adjacent digit lines of the digit lines. The memory device may include multiple plates and multiple plate groups each including a group of the memory cell coupled to a plate of the multiple plates directly and coupled to a group of respective sense amplifiers through a group of respective digit lines, as discussed above for memory device 400. The memory device may be a ferroelectric memory device.

At operation 1582, one or more switching signals are received. The one or more switching signals are each indicative of a logic state of a digit line of the one or more adjacent digit lines. In one example, the target digit line and the one or more adjacent digit lines are coupled to respective target sense amplifier and one or more adjacent sense amplifiers. The one or more switching signals may each be received by the output stage of the target sense amplifier from the output stage of an adjacent sense amplifier of the one or more adjacent sense amplifiers. In one example, the one or more switching signals may each be received by the output stage of the target sense amplifier from the input to the output stage of the adjacent sense amplifier through a buffer or inverter.

At operation 1583, a slew rate of the output signal in the target digit line is controlled using the received one or more switching signals. The slew rate of the output signal may be controlled for increasing a speed of accessing the memory cells without causing disturbance. In an example, the speed of accessing the memory cells is increased without causing disturbance by increasing the slew rate of the output signal in the target digit line while interference to the one or more adjacent digit lines is maintained under a specified level. In one example, the output stage of the sense amplifier includes multiple biasing devices. The slew rate of the output signal is controlled by activating a biasing device of the multiple biasing devices using each signal of the received one or more switching signals. In another example, the output stage of the sense amplifier includes one or more decoupling capacitors coupled to the target digit line through one or more respective switches. The slew rate of the output signal is controlled by using the received one or more switching signals to drive the one or more respective switches.

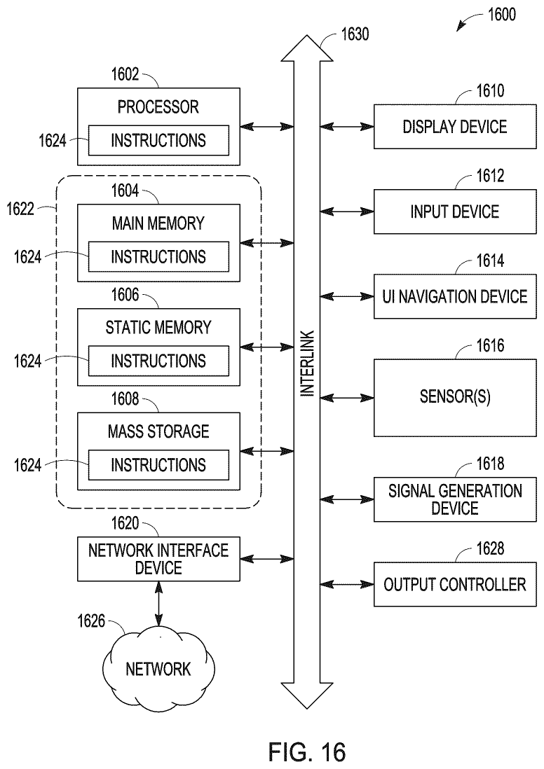

FIG. 16 illustrates a block diagram of an example machine 1600 with which, in which, or by which any one or more of the techniques (e.g., circuits or methods) discussed herein can be implemented. Examples, as discussed herein, can include, or can operate by, logic or a number of components, or mechanisms in machine 1600. Circuitry (e.g., circuitry for accessing memory cells) is a collection of circuits implemented in tangible entities of machine 1600 that include hardware (e.g., simple circuits, gates, logic, etc.). Circuitry membership can be flexible over time. Circuitries include members that can, alone or in combination, perform specified operations when operating. In an example, the hardware of the circuitry can include variably connected physical components (e.g., execution units, transistors, simple circuits, etc.) including a machine-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time.

In alternative embodiments, machine 1600 can operate as a standalone device or can be connected (e.g., networked) to other machines. In a networked deployment, machine 1600 can operate in the capacity of a server machine, a client machine, or both in server-client network environments. In an example, machine 1600 can act as a peer machine in peer-to-peer (P2P) (or other distributed) network environment. Machine 1600 can be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Machine 1600 (e.g., computer system) can include a hardware processor 1602 or host device (e.g., a central processing unit (CPU), a graphics processing unit (GPU), a hardware processor core, or any combination thereof), a main memory 1604, a static memory 1606 (e.g., memory or storage for firmware, microcode, a basic-input-output (BIOS), unified extensible firmware interface (UEFI), etc.), and mass storage device 1608 or memory die stack (e.g., a memory die stack, hard drives, tape drives, flash storage, or other block devices) some or all of which can communicate with each other via an interlink 1630 (e.g., bus). Machine 1600 can further include a display device 1610, an alphanumeric input device 1612 (e.g., a keyboard), and a user interface (UI) Navigation device 1614 (e.g., a mouse). In an example, display device 1610, input device 1612, and UI navigation device 1614 can be a touch screen display. Machine 1600 can additionally include a mass storage device 1608 (e.g., a drive unit), a signal generation device 1618 (e.g., a speaker), a network interface device 1620, and one or more sensor(s) 1616, such as a global positioning system (GPS) sensor, compass, accelerometer, or other sensor. Machine 1600 can include an output controller 1628, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of hardware processor 1602, main memory 1604, static memory 1606, or mass storage device 1608 can be, or include, a machine-readable media 1622 on which is stored one or more sets of data structures or instructions 1624 (e.g., software) embodying or used by any one or more of the techniques or functions discussed herein. Instructions 1624 can also reside, completely or at least partially, within any of registers of hardware processor 1602, main memory 1604, static memory 1606, or mass storage device 1608 during execution thereof by machine 1600. In an example, one or any combination of hardware processor 1602, main memory 1604, static memory 1606, or mass storage device 1608 can constitute machine-readable media 1622. While machine-readable media 1622 is illustrated as a single medium, the term “machine-readable medium” can include a single medium or multiple media (e.g., a centralized or distributed database, or associated caches and servers) configured to store one or more instructions 1624.

The term “machine-readable medium” can include any medium that is capable of storing, encoding, or carrying instructions for execution by machine 1600 and that cause machine 1600 to perform any one or more of the techniques of the present disclosure, or that is capable of storing, encoding or carrying data structures used by or associated with such instructions. Non-limiting machine-readable medium examples can include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine readable media that do not include transitory propagating signals. Specific examples of non-transitory machine-readable media can include: non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks.

In an example, information stored or otherwise provided on machine-readable media 1622 can be representative of instructions 1624, such as instructions 1624 themselves or a format from which instructions 1624 can be derived. This format from which instructions 1624 can be derived can include source code, encoded instructions (e.g., in compressed or encrypted form), packaged instructions (e.g., split into multiple packages), or the like. The information representative of instructions 1624 in machine-readable media 1622 can be processed by processing circuitry into the instructions to implement any of the operations discussed herein. For example, deriving instructions 1624 from the information (e.g., processing by the processing circuitry) can include: compiling (e.g., from source code, object code, etc.), interpreting, loading, organizing (e.g., dynamically or statically linking), encoding, decoding, encrypting, unencrypting, packaging, unpackaging, or otherwise manipulating the information into instructions 1624.

In an example, the derivation of instructions 1624 can include assembly, compilation, or interpretation of the information (e.g., by the processing circuitry) to create instructions 1624 from some intermediate or preprocessed format provided by machine-readable media 1622. The information, when provided in multiple parts, can be combined, unpacked, and modified to create instructions 1624. For example, the information can be in multiple compressed source code packages (or object code, or binary executable code, etc.) on one or several remote servers. The source code packages can be encrypted when in transit over a network and decrypted, uncompressed, assembled (e.g., linked) if necessary, and compiled or interpreted (e.g., into a library, stand-alone executable etc.) at a local machine, and executed by the local machine.

Instructions 1624 can be further transmitted or received over a communications network 1626 using a transmission medium via network interface device 1620 utilizing any one of a number of transfer protocols (e.g., frame relay, internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), plain old telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 1620 can include one or more physical jacks (e.g., Ethernet, coaxial, or phone jacks) or one or more antennas to connect to network 1626. In an example, network interface device 1620 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by machine 1600, and includes digital or analog communications signals or other intangible medium to facilitate communication of such software. A transmission medium is a machine-readable medium.

Some non-limiting examples (Examples 1-20) of the present subject matter are provided as follows:

In Example 1, an electronic device may include multiple memory cells, multiple digit lines, and multiple sense amplifiers. The multiple sense amplifiers may each be coupled to a respective memory cell of the multiple memory cells through a target digit line of the multiple digit lines. Each sense amplifier of the multiple amplifiers may include an output stage configured to produce an output signal driving the target digit line. The target digit line may be directly adjacent to one or more adjacent digit lines of the multiple digit lines. The output stage may be configured to receive one or more switching signals each indicative of a logic state of a digit line of the one or more adjacent digit lines and to control a slew rate of the output signal in the target digit line using the received one or more switching signals.

In Example 2, the subject matter of Example 1 may optionally be configured such that the multiple memory cells each include a ferroelectric capacitor and a selection component. The ferroelectric capacitor is coupled to a digit line of the multiple digit lines through the selection component.

In Example 3, the subject matter of any one or a combination of Examples 1 and 2 may optionally be configured such that the output stage is configured to receive the one or more switching signals from one or more adjacent sense amplifiers of the multiple sense amplifiers. The one or more adjacent sense amplifiers are coupled to and correspond to the one or more adjacent digit lines.

In Example 4, the subject matter of Example 3 may optionally be configured such that the output stage is configured to receive, via a buffer or inverter, each switching signal of the one or more switching signals from an input of the output stage of an adjacent sense amplifier of the one or more adjacent sense amplifiers.

In Example 5, the subject matter of any one or any combination of Examples 1 to 4 may optionally be configured such that the output stage includes multiple biasing devices coupled to the target digit line, and one or more biasing devices of the multiple biasing devices are each configured to receive a switching signal of the one or more switching signals and to be activated by that received switching signal.

In Example 6, the subject matter of Example 5 may optionally be configured such that the one or more biasing devices each include PMOS transistors.

In Example 7, the subject matter of Example 5 may optionally be configured such that the one or more biasing devices each include NMOS transistors.

In Example 8, the subject matter of any one or any combination of Examples 1 to 4 may optionally be configured such that the output stage includes one or more decoupling capacitors coupled to the target digit line through respective one or more switches each configured to receive a switching signal of the one or more switching signals and to be activated by that received switching signal for connecting the respective decoupling capacitor to the target digit line.

In Example 9, a memory device may include multiple plates and multiple plate groups. The multiple plate groups may each include a plate of the multiple plates, a memory cell group including memory cells, a digit line group including digit lines, and a sense amplifier group including sense amplifiers. The memory cells of the memory cell group may be coupled to the plate and coupled to respective sense amplifiers of the sense amplifier group through respective digit lines of the digit line group. Each sense amplifier of the sense amplifier group may include an output stage configured to produce an output current driving a target digit line being the respective digit line. The target digit line may be directly adjacent to one or more adjacent digit lines of the digit line group. The output stage may be configured to receive one or more switching signals each indicative of a logic state of a digit line of the one or more adjacent digit lines and to control a slew rate of the output signal in the target digit line using the received one or more switching signals.

In Example 10, the subject matter of Example 9 may optionally be configured such that the multiple memory cells each includes a ferroelectric capacitor.

In Example 11, the subject matter of any one or a combination of Examples 9 and 10 may optionally be configured such that the output stage is configured to receive the one or more switching signals from one or more adjacent sense amplifiers of the multiple sense amplifiers. The one or more adjacent sense amplifiers are coupled to and correspond to the one or more adjacent digit lines.

In Example 12, the subject matter of any one or any combination of Examples 9 to 11 may optionally be configured such that the output stage includes multiple biasing devices coupled to the target digit line and including one or more biasing devices each configured to receive a switching signal of the one or more switching signals and to be activated by that received switching signal.

In Example 13, the subject matter of any one or any combination of Examples 9 to 11 may optionally be configured such that the output stage includes one or more decoupling capacitors coupled to the target digit line through respective one or more switches each configured to receive a switching signal of the one or more switching signals and to be activated by that received switching signal for connecting the respective decoupling capacitor to the target digit line.

In Example 14, a method is provided. The method may include accessing memory cells using sense amplifiers coupled to the memory cells through digit lines. The sense amplifiers may each be coupled to a respective memory cell of the memory cells through a target digit line of digit lines and include an output stage configured to produce an output signal driving the target digit line. The target digit line may be directly adjacent to one or more adjacent digit lines of the digit lines. The method may further include: receiving one or more switching signals each indicative of a logic state of a digit line of the one or more adjacent digit lines; and controlling a slew rate of the output signal using the received one or more switching signals.

In Example 15, the subject matter of controlling the slew rate of the output signal as found in Example 14 may optionally include increasing the slew rate to increase a speed of accessing the memory cells while maintaining interference to the one or more adjacent digit lines under a specified level.

In Example 16, the subject matter of receiving the one or more switching signals as found in any one or a combination of Examples 14 and 15 may optionally include receiving the one or more switching signals from one or more adjacent sense amplifiers of the sense amplifiers. The one or more adjacent sense amplifiers are coupled to and correspond to the one or more adjacent digit lines.

In Example 17, the subject matter of receiving the one or more switching signals from the one or more adjacent sense amplifiers as found in Example 16 may optionally include receiving each switching signal of the one or more switching signals from an input of the output stage of an adjacent sense amplifier of the one or more adjacent sense amplifiers through a buffer or inverter.

In Example 18, the output stage as found in any one or any combination of Examples 14 to 17 may optionally include multiple biasing devices, and the subject matter of controlling the slew rate of the output signal using the received one or more switching signals as found in any one or a combination of Examples 14 to 17 may optionally include activating a biasing device of the biasing devices using each signal of the received one or more switching signals.

In Example 19, the output stage as found in any one or any combination of Examples 14 to 17 may optionally include multiple biasing devices, and the subject matter of controlling the slew rate of the output signal using the received one or more switching signals as found in any one or a combination of Examples 14 to 17 may optionally include one or more decoupling capacitors coupled to the respective digit line through one or more respective switches, and the subject matter of controlling the slew rate of the output signal using the received one or more switching signals as found in any one or a combination of Examples 14 to 17 may optionally include using the received one or more switching signals to drive the one or more respective switches.

In Example 20, the subject matter of accessing the memory cells as found in any one or any combination of Examples 14 to 19 may optionally include accessing in the memory cells of a memory device including multiple plates and multiple plate groups each including a group of the memory cell coupled to a plate of the multiple plates directly and coupled to a group of respective sense amplifiers through a group of respective digit lines.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or discussed. However, the present inventors also contemplate examples in which only those elements shown or discussed are provided. Moreover, the present inventors also contemplate examples using any combination or permutation of those elements shown or discussed (or one or more aspects thereof), either with respect to a particular example (or one or more aspects thereof), or with respect to other examples (or one or more aspects thereof) shown or discussed herein.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either coupled, or directly coupled, unless otherwise indicated.

The above description is intended to be illustrative, and not restrictive. For example, the above-discussed examples (or one or more aspects thereof) may be used in combination with each other. Other embodiments can be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An electronic device, comprising:
multiple memory cells,
multiple digit lines, and
multiple sense amplifiers each coupled to a respective memory cell of the multiple memory cells through a target digit line of the multiple digit lines, each sense amplifier of the multiple sense amplifiers including an output stage configured to produce an output signal driving the target digit line,
wherein the target digit line is directly adjacent to one or more adjacent digit lines of the multiple digit lines, and the output stage is configured to receive one or more switching signals each indicative of a logic state of a digit line of the one or more adjacent digit lines and to control a slew rate of the output signal in the target digit line using the received one or more switching signals.

2. The electronic device of claim 1, wherein the multiple memory cells each comprise a ferroelectric capacitor and a selection component, the ferroelectric capacitor coupled to a digit line of the multiple digit lines through the selection component.

3. The electronic device of claim 1, wherein the output stage is configured to receive the one or more switching signals from one or more adjacent sense amplifiers of the multiple sense amplifiers, the one or more adjacent sense amplifiers coupled to and corresponding to the one or more adjacent digit lines.

4. The electronic device of claim 3, wherein the output stage is configured to receive, via a buffer or inverter, each switching signal of the one or more switching signals from an input of the output stage of an adjacent sense amplifier of the one or more adjacent sense amplifiers.

5. The electronic device of claim 1, wherein the output stage comprises multiple biasing devices coupled to the target digit line, and one or more biasing devices of the multiple biasing devices are each configured to receive a switching signal of the one or more switching signals and to be activated by that received switching signal.

6. The electronic device of claim 5, wherein the one or more biasing devices each comprise PMOS transistors.

7. The electronic device of claim 5, wherein the one or more biasing devices each comprise NMOS transistors.

8. The electronic device of claim 1, wherein the output stage comprises one or more decoupling capacitors coupled to the target digit line through respective one or more switches each configured to receive a switching signal of the one or more switching signals and to be activated by that received switching signal for connecting the respective decoupling capacitor to the target digit line.

9. A memory device, comprising:
multiple plates; and
multiple plate groups each including a plate of the multiple plates, a memory cell group including memory cells, a digit line group including digit lines, and a sense amplifier group including sense amplifiers, the memory cells of the memory cell group coupled to the plate and coupled to respective sense amplifiers of the sense amplifier group through respective digit lines of the digit line group, each sense amplifier of the sense amplifier group including an output stage configured to produce an output current driving a target digit line being the respective digit line, the target digit line directly adjacent to one or more adjacent digit lines of the digit line group, the output stage configured to receive one or more switching signals each indicative of a logic state of a digit line of the one or more adjacent digit lines and to control a slew rate of the output signal in the target digit line using the received one or more switching signals.

10. The memory device of claim 9, wherein the multiple memory cells each comprise a ferroelectric capacitor.

11. The memory device of claim 10, wherein the output stage is configured to receive the one or more switching signals from one or more adjacent sense amplifiers of the multiple sense amplifiers, the one or more adjacent sense amplifiers coupled to and corresponding to the one or more adjacent digit lines.

12. The memory device of claim 11, wherein the output stage comprises multiple biasing devices coupled to the target digit line and including one or more biasing devices each configured to receive a switching signal of the one or more switching signals and to be activated by that received switching signal.

13. The memory device of claim 11, wherein the output stage comprises one or more decoupling capacitors coupled to the target digit line through respective one or more switches each configured to receive a switching signal of the one or more switching signals and to be activated by that received switching signal for connecting the respective decoupling capacitor to the target digit line.

14. A method, comprising:
accessing memory cells using sense amplifiers coupled to the memory cells through digit lines, the sense amplifiers each coupled to a respective memory cell of the memory cells through a target digit line of digit lines and including an output stage configured to produce an output signal driving the target digit line, the target digit line directly adjacent to one or more adjacent digit lines of the digit lines;
receiving one or more switching signals each indicative of a logic state of a digit line of the one or more adjacent digit lines; and
controlling a slew rate of the output signal using the received one or more switching signals.

15. The method of claim 14, wherein controlling the slew rate of the output signal comprises increasing the slew rate to increase a speed of accessing the memory cells while maintaining interference to the one or more adjacent digit lines under a specified level.

16. The method of claim 14, wherein receiving the one or more switching signals comprises receiving the one or more switching signals from one or more adjacent sense amplifiers of the sense amplifiers, the one or more adjacent sense amplifiers coupled to and corresponding to the one or more adjacent digit lines.

17. The method of claim 16, wherein receiving the one or more switching signals from the one or more adjacent sense amplifiers comprises receiving each switching signal of the one or more switching signals from an input of the output stage of an adjacent sense amplifier of the one or more adjacent sense amplifiers through a buffer or inverter.

18. The method of claim 16, wherein the output stage comprises multiple biasing devices, and controlling the slew rate of the output signal using the received one or more switching signals comprises activating a biasing device of the biasing devices using each signal of the received one or more switching signals.

19. The method of claim 16, wherein the output stage comprises one or more decoupling capacitors coupled to the respective digit line through one or more respective switches, and controlling the slew rate of the output signal using the received one or more switching signals comprises using the received one or more switching signals to drive the one or more respective switches.

20. The method of claim 14, wherein accessing the memory cells comprises accessing in the memory cells of a memory device including multiple plates and multiple plate groups each including a group of the memory cell coupled to a plate of the multiple plates directly and coupled to a group of respective sense amplifiers through a group of respective digit lines.
